(19) United States
(12) Patent Application Publication
(10) Pub. No.: US 2012/0147575 A1
(43) Pub. Date: Jun. 14, 2012

(54) ELECTRONIC DEVICE

(75) Inventors: CHUNG-CHENG HSIEH, Tu-Cheng (TW); LI-PING CHEN, Tu-Cheng (TW)

(73) Assignee: HON HAI PRECISION INDUSTRY CO., LTD., Tu-Cheng (TW)

(21) Appl. No.: 13/188,183

(22) Filed: Jul. 21, 2011

(30) Foreign Application Priority Data
Dec. 8, 2010 (TW) 99142901

(51) Int. Cl. H05K 5/00

(52) U.S. Cl. 361/759

(57) ABSTRACT

An electronic device includes a circuit board, a chassis, a mounting member, a positioning member, and a locking member. The chassis comprises a bottom plate with a locking hole. The mounting member is secured to the circuit board. The positioning member is mounted to the mounting member and located between the circuit board and the bottom plate. The locking member is mounted to the positioning member from outside of the bottom plate and through the locking hole.

### BACKGROUND

1. Technical Field

The present disclosure relates to an electronic device with a circuit board.

2. Description of Related Art

Motherboards are often secured to a bottom plate of a computer chassis by a first locking member and a second locking member. Usually, the motherboard defines a first locking hole, and the bottom plate defines a second locking hole. The first locking member defines a threaded hole and is mounted to the second locking member. The second locking member is externally threaded and screwed into the threaded hole through the first locking hole, to secure the motherboard to the bottom plate. However, the first locking hole may be covered by components secured to the motherboard making it difficult to insert the second locking member. Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an electronic device in accordance with an embodiment.

FIG. 2 is an assembled, isometric view of FIG. 1.

FIG. 3 is a cross section view of FIG. 2.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

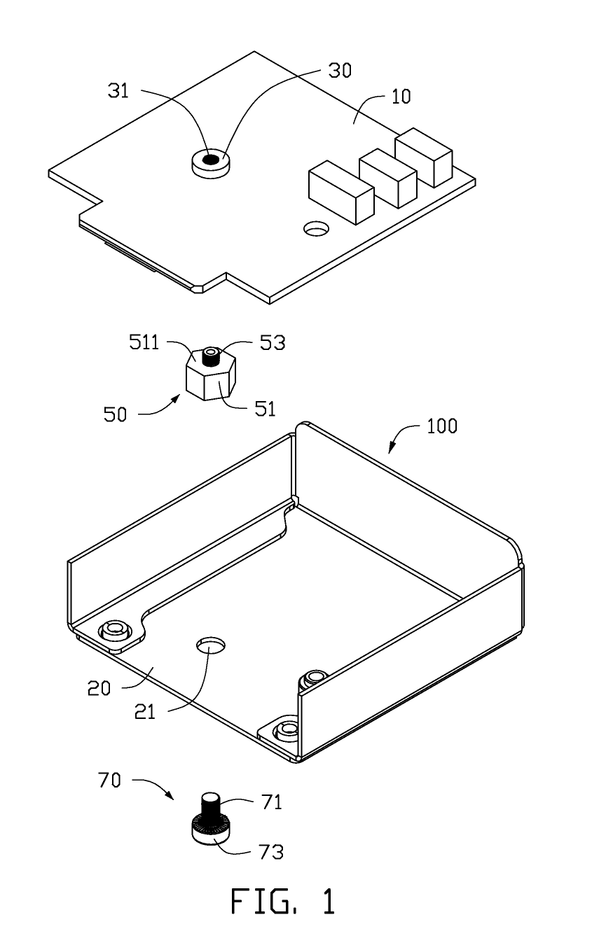

Referring to FIG. 1, an electronic device in accordance with an embodiment includes a circuit board 10, a chassis 100, a mounting member 30, a positioning member 50 and a locking member 70. In one embodiment, the circuit board 10 is a main board.

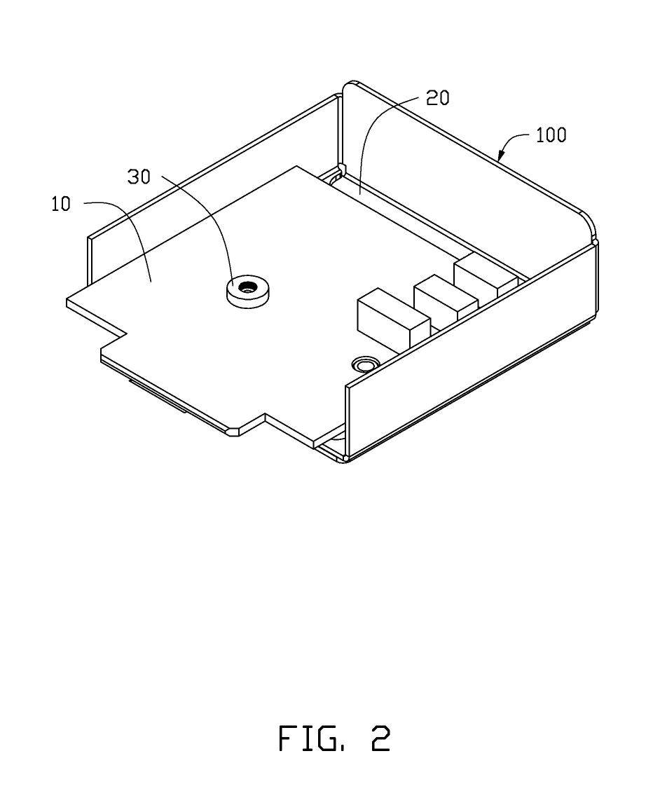

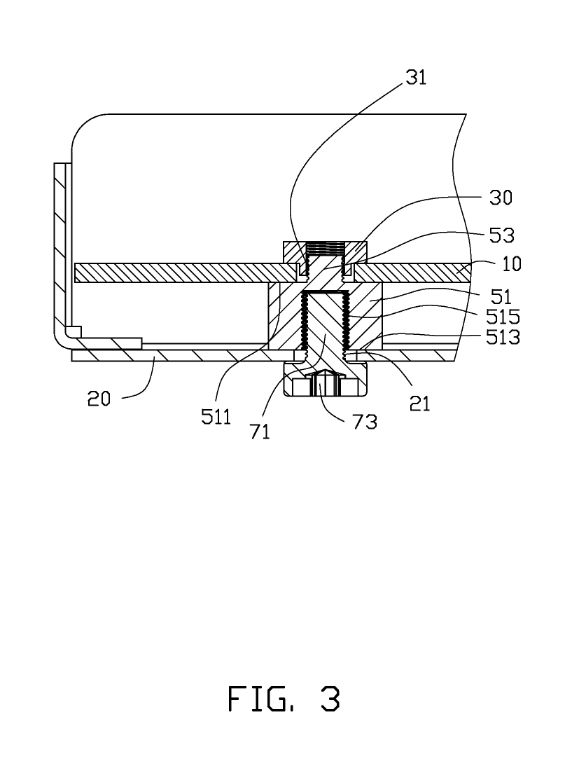

Referring to FIGS. 1-3, the chassis 100 includes a bottom plate 20. The circuit board 10 is mounted to the bottom plate 20. The bottom plate 20 defines a plurality of locking holes 21. In one embodiment, the locking holes 21 are round.

The mounting member 30 is secured to the circuit board 10 by soldering, riveting or other securing method. The mounting member 30 defines a first threaded hole 31.

The positioning member 50 includes a maintaining portion 51 and a mounting portion 53. The maintaining portion 51 includes a top surface 511 and a bottom surface 513 opposite to the top surface 511. In one embodiment, the top surface 511 is substantially parallel to the bottom surface 513. The mounting portion 53 extends from the top surface 511, and is externally threaded. The bottom surface 513 defines a second threaded hole 515. A depth of the second threaded hole 515 is smaller than a distance between the top surface 511 and the bottom surface 513. In one embedment, the maintaining portion 51 is hexagonal.

The locking member 70 includes a locking portion 71 and an operating portion 73. The diameter of the locking portion 71 is substantially equal to that of the locking hole 21 and the second threaded hole 515. The locking portion 71 corresponds to the second threaded hole 515, and is externally threaded. In this embodiment, the locking member 70 is a screw.

In assembly, the positioning member 50 is moved to align the mounting portion 53 with the first threaded hole 31. The mounting portion 53 is screwed into the first threaded hole 31 until the bottom surface of the circuit board 10 abuts the top surface 511 of the maintain portion 51. The circuit board 10 with the positioning member 50 is moved towards the top surface of the bottom plate 20, to align the second threaded hole 515 with the locking hole 21. The locking portion 71 is inserted through the locking hole 21 from the bottom surface of the bottom plate 20, and then screwed into the second threaded hole 515 until the bottom surface 513 abuts the top surface of the bottom plate 20. The operating portion 73 abuts the bottom surface of the bottom plate 20. The circuit board 10 is secured to the bottom plate 20 thereby.

In disassembly, the locking portion 73 is unscrewed from the second threaded hole 515, then the circuit board 10 can be removed from the bottom plate 20. The mounting portion 53 is unscrewed from the first threaded hole 31, then the positioning member 50 can be removed from the circuit board 10.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. An electronic device comprising:
a circuit board;
a chassis comprising a bottom plate with a locking hole;
a mounting member secured to the circuit board;
a positioning member mounted to the mounting member and located between the circuit board and the bottom plate; and
a locking member mounted to the positioning member from outside of the bottom plate and through the locking hole.

2. The electronic device of claim 1, wherein the positioning member comprises a maintaining portion and a mounting portion extends from the maintaining portion, the mounting portion is mounted to the mounting member, and the maintaining portion is sandwiched between the circuit board and the bottom plate.

3. The electronic device of claim 2, wherein the mounting member defines a first threaded hole, the mounting portion is externally threaded and screwed into the first threaded hole.

4. The electronic device of claim 2, wherein the maintaining portion defines a second threaded hole, the locking member is externally threaded and screwed into the second threaded hole.

5. The electronic device claim 4, wherein the maintaining portion comprises a top surface and a bottom surface opposite to the top surface, the mounting portion extends from the top surface, and the second threaded hole is defined in the bottom surface.

6. The electronic device of claim 5, wherein the top surface is substantially parallel to the bottom surface.

7. The electronic device of claim 5, wherein a depth of the second threaded hole is smaller than a distance between the top surface and the bottom surface .

8. The electronic device of claim 5, wherein the circuit board abuts the top surface, and the bottom plate abuts the bottom surface.

9. The electronic device of claim 1, wherein the locking member is a screw.

10. The electronic device of claim 2, wherein the cross-section of the maintaining portion is hexagonal.

11. An electronic device comprising:
a circuit board;
a chassis comprising a bottom plate with a locking hole;
a mounting member, secured to the circuit board, defining a first threaded hole;
a positioning member comprising a maintaining portion and a mounting portion extends from the maintaining portion; and
a locking member;
wherein the mounting portion is screwed into the first threaded hole, and the maintaining portion is sandwiched between the circuit board and the bottom plate mounting portion; the locking member is mounted to the positioning member from outside the bottom plate and through the locking hole.

12. The electronic device claim 11, wherein the maintaining portion defines a second threaded hole, the locking member is externally threaded and screwed into the second threaded hole.

13. The electronic device of claim 12, wherein the maintaining portion comprises a top surface and a bottom surface opposite to the top surface, the mounting portion extends from the top surface, and the second threaded hole is defined in the bottom surface.

14. The electronic device of claim 13, wherein the top surface is substantially parallel the bottom surface.

15. The electronic device of claim 13, wherein a depth of the second threaded hole is smaller than a distance between the top surface and the bottom surface.

16. The electronic device of claim 13, wherein the circuit board abuts the top surface, and the bottom plate abuts the bottom surface.

17. The electronic device of claim 11, wherein the locking member is a screw.

18. The electronic device of claim 11, wherein the cross-section of the maintaining portion is hexagonal.
